(19) United States
(12) Patent Application Publication
(10) Pub. No.: US 2025/0054841 A1
(43) Pub. Date: Feb. 13, 2025

(54) PACKAGE AND SEMICONDUCTOR DEVICE

(71) Applicant: Sumitomo Electric Device Innovations, Inc., Yokohama-shi (JP)

(72) Inventor: Ikuo NAKASHIMA, Yokohama-shi (JP)

(73) Assignee: Sumitomo Electric Device Innovations, Inc., Yokohama-shi (JP)

(21) Appl. No.: 18/654,450

(22) Filed: May 3, 2024

(30) Foreign Application Priority Data
Aug. 7, 2023 (JP) 2023-128738

(51) Int. Cl. H01L 23/495; H01L 23/00; H01L 23/047; H01L 23/10; H01L 23/29; H01L 23/31; H01L 25/16

(52) U.S. Cl. CPC H01L 23/4952; H01L 23/047; H01L 23/10; H01L 23/293; H01L 23/3142; H01L 23/49541; H01L 23/49582; H01L 24/48; H01L 25/16; H01L 2224/48195; H01L 2924/1616; H01L 2924/16251; H01L 2924/17787; H01L 2924/19041; H01L 2924/19105

(57) ABSTRACT

A package includes a base having a mounting region on which a semiconductor chip is to be mounted, a frame provided on the base so as to surround the mounting region, a first metal layer provided on an upper surface of the frame, the first metal layer including a first portion to which a first bonding wire electrically connecting the semiconductor chip is to be bonded, a second portion farther from the mounting region than the first portion, and a first connecting portion connecting the first portion to the second portion, a first insulating layer provided on the first connecting portion in contact with the first connecting portion, the first insulating layer crossing the first metal layer, and a first lead bonded on the second portion.

### CROSS REFERENCE TO RELATED APPLICATIONS

This application claims priority based on Japanese Patent Application No. 2023-128738 filed on Aug. 7, 2023, and the entire contents of the Japanese patent applications are incorporated herein by reference.

### FIELD

A certain aspect of the embodiments is related to a package and a semiconductor device.

### BACKGROUND

It is known that a frame surrounding a semiconductor chip mounted on a base is provided on the base, and a feed-through for electrically connecting the semiconductor chip to the outside is provided in each opening of the frame and on the base (for example, Patent Document 1: Japanese Laid-Open Patent Application No. 2018-113284).

### SUMMARY

A package device according to the present disclosure includes: a base having a mounting region on which a semiconductor chip is to be mounted; a frame provided on the base so as to surround the mounting region; a first metal layer provided on an upper surface of the frame, the first metal layer including a first portion to which a first bonding wire electrically connecting the semiconductor chip is to be bonded, a second portion farther from the mounting region than the first portion, and a first connecting portion connecting the first portion to the second portion; a first insulating layer provided on the first connecting portion in contact with the first connecting portion, the first insulating layer crossing the first metal layer; and a first lead bonded on the second portion.

A package device according to the present disclosure includes: a base having a mounting region on which a semiconductor chip is to be mounted; a frame provided on the base so as to surround the mounting region; a first metal layer provided on an upper surface of the frame, the first metal layer including a first portion to which a first bonding wire electrically connecting the semiconductor chip is to be bonded, and a second portion farther from the mounting region than the first portion and separated from the first portion on an upper surface of the frame; a first wiring provided in the frame and electrically connecting the first portion to the second portion; and a first lead bonded on the second portion; wherein the upper surface of the frame is exposed from the first metal layer so as to cross the first metal layer in a region separating the first portion and the second portion.

### BRIEF DESCRIPTION OF DRAWINGS

FIG. 1 is a plan view of a semiconductor device according to a first embodiment.

FIG. 2 is a cross-sectional view taken along a line A-A in FIG. 1.

FIG. 3 is a plan view of the semiconductor device mounted on a housing according to the first embodiment.

FIG. 4 is a cross-sectional view taken along a line A-A in FIG. 3.

FIG. 5A is a diagram illustrating a method of manufacturing a package according to the first embodiment.

FIG. 5B is a diagram illustrating a method of manufacturing the package according to the first embodiment.

FIG. 6A is a diagram illustrating a method of manufacturing the package according to the first embodiment.

FIG. 6B is a diagram illustrating a method of manufacturing the package according to the first embodiment.

FIG. 7A is a diagram illustrating a method of manufacturing the package according to the first embodiment.

FIG. 7B is a diagram illustrating a method of manufacturing the package according to the first embodiment.

FIG. 8A is a diagram illustrating a method of manufacturing the package according to the first embodiment.

FIG. 8B is a diagram illustrating a method of manufacturing the package according to the first embodiment.

FIG. 9 is a diagram illustrating a method of manufacturing the package according to the first embodiment.

FIG. 10 is an enlarged plan view of a semiconductor device according to a first comparative example.

FIG. 11 is a cross-sectional view taken along a line A-A of FIG. 10.

FIG. 12 is an enlarged plan view of the semiconductor device according to the first embodiment.

FIG. 13 is a cross-sectional view taken along a line A-A of FIG. 12.

FIG. 14 is a plan view of a semiconductor device according to a second embodiment.

FIG. 15 is a cross-sectional view taken along a line A-A of FIG. 14.

FIG. 16 is a cross-sectional view taken along a line B-B of FIG. 14.

FIG. 17 is an enlarged cross-sectional view of a semiconductor device according to a second comparative example.

FIG. 18 is an enlarged cross-sectional view of a semiconductor device according to a second embodiment.

FIG. 19 is a plan view of a semiconductor device according to a third embodiment.

FIG. 20 is a cross-sectional view taken along a line A-A of FIG. 19.

FIG. 21 is a plan view of a semiconductor device according to a fourth embodiment.

FIG. 22 is a cross-sectional view taken along a line A-A of FIG. 21.

FIG. 23 is an enlarged plan view of a semiconductor device according to the fourth embodiment.

FIG. 24 is a cross-sectional view taken along a line A-A of FIG. 23.

### DETAILED DESCRIPTION OF EMBODIMENTS

The package having the feed-through is expensive because of the complicated structure. Therefore, a structure is conceivable in which a metal layer is provided on the upper surface of the frame, and a bonding wire and a lead connected to the semiconductor chip are bonded to the metal layer. However, in this case, the solder or the like for mounting the lead on the external substrate may wet and spread from the lead to the metal layer, and may reach the bonding wire. This may cause a defect such as breakage of the bonding wire.

The present disclosure has been made in view of the above problems, and an object thereof is to suppress the defect of the bonding wire.

### Details of Embodiments of the Present Disclosure

First, the contents of the embodiments of this disclosure are listed and explained.
(1) A package according to the present disclosure includes: a base having a mounting region on which a semiconductor chip is to be mounted; a frame provided on the base so as to surround the mounting region; a first metal layer provided on an upper surface of the frame, the first metal layer including a first portion to which a first bonding wire electrically connecting the semiconductor chip is to be bonded, a second portion farther from the mounting region than the first portion, and a first connecting portion connecting the first portion to the second portion; a first insulating layer provided on the first connecting portion in contact with the first connecting portion, the first insulating layer crossing the first metal layer; and a first lead bonded on the second portion. This can suppress the solder from spreading to the first portion and causing a defect in the first bonding wire.
(2) In the above (1), each of the frame and the first insulating layer may have ceramics as a main component. This can suppress a thermal stress.
(3) In the above (1) or (2), a wettability of a surface of the first insulating layer with a solder may be worse than a wettability of a surface of the first metal layer with the solder. This can suppress the solder from spreading on the surface of the first insulating layer.
(4) In any one of the above (1) to (3), the package further may include: a second metal layer provided on an upper surface of the frame, the second metal layer including a third portion to which a second bonding wire electrically connecting the semiconductor chip is to be bonded, a fourth portion farther from the mounting region than the third portion, and a second connecting portion connecting the third portion to the fourth portion; a second insulating layer provided on the second connecting portion in contact with the second connecting portion, the second insulating layer crossing the second metal layer; and a second lead bonded on the fourth portion. This can suppress the solder from spreading to the third portion and causing a defect in the second bonding wire.
(5) A package according to the present disclosure includes: a base having a mounting region on which a semiconductor chip is to be mounted; a frame provided on the base so as to surround the mounting region; a first metal layer provided on an upper surface of the frame, the first metal layer including a first portion to which a first bonding wire electrically connecting the semiconductor chip is to be bonded, and a second portion farther from the mounting region than the first portion and separated from the first portion on an upper surface of the frame; a first wiring provided in the frame and electrically connecting the first portion to the second portion; and a first lead bonded on the second portion; wherein the upper surface of the frame is exposed from the first metal layer so as to cross the first metal layer in a region separating the first portion and the second portion. This can suppress the solder from spreading to the first portion and causing a defect in the first bonding wire.
(6) In the above (5), a wettability of a surface of the frame with a solder may be worse than a wettability of a surface of the first metal layer with the solder. This can suppress the solder from spreading on the surface of the frame.
(7) In the above (5) or (6), the package further may include: a second metal layer provided on the upper surface of the frame, the second metal layer including a third portion to which a second bonding wire electrically connecting the semiconductor chip is to be bonded, and a fourth portion farther from the mounting region than the third portion; a second wiring provided in the frame and electrically connecting the third portion to the fourth portion; and a second lead bonded on the fourth portion; wherein the upper surface of the frame is exposed from the second metal layer so as to cross the second metal layer in a region separating the third portion and the fourth portion. This can prevent the solder from spreading to the third portion and causing a defect in the second bonding wire.
(8) A package according to the present disclosure includes: the package according to the above (1); and the semiconductor chip mounted on the base. Thus, the semiconductor chip can be mounted.
(9) In the above (8), the semiconductor device may include a resin sealing material bonded to the upper surface of the frame and an upper surface of the first metal layer to seal the semiconductor chip. This can suppress the solder from being transmitted between the first metal layer and the resin sealing material.
(10) A package according to the present disclosure includes: the package according to the above (2); the semiconductor chip mounted on the base; and a lid bonded to the upper surface of the frame and an upper surface of the first insulating layer by using a resin adhesive to seal the semiconductor chip. This can suppress the solder from being transmitted between the resin adhesive and the first metal layer.
(11) A package according to the present disclosure includes: the package according to the above (5); and the semiconductor chip mounted on the base. Thus, the semiconductor chip can be mounted.
(12) In the above (11), the semiconductor device may include a resin sealing material bonded to the upper surface of the frame and an upper surface of the first metal layer to seal the semiconductor chip. This can suppress the solder from being transmitted between the first metal layer and the resin sealing material.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

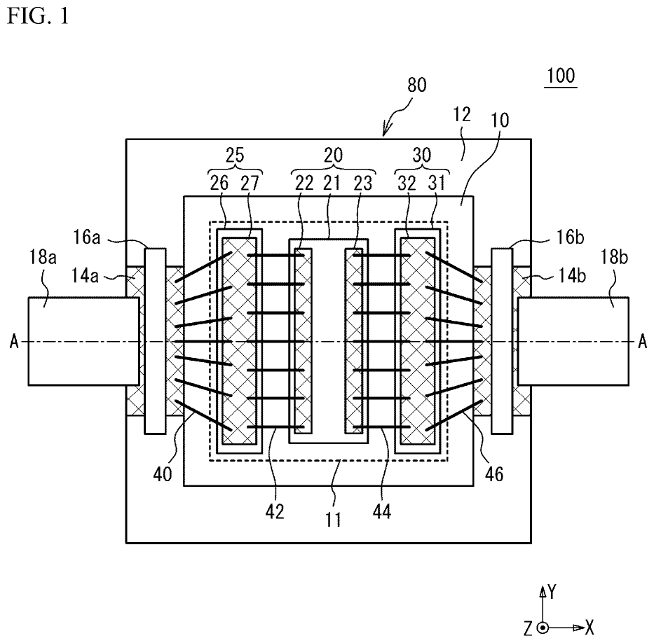

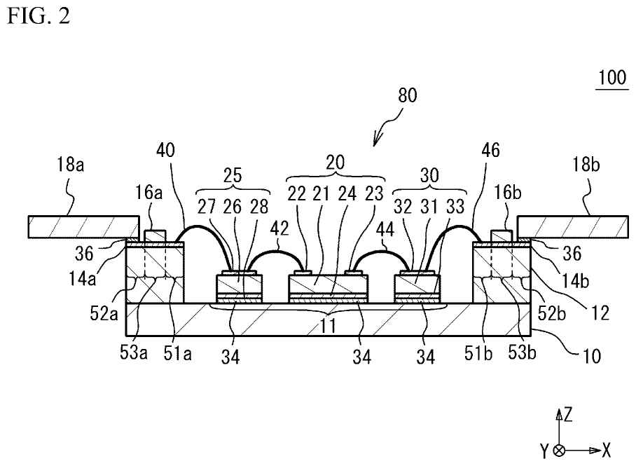

FIG. 1 is a plan view of a semiconductor device according to a first embodiment. FIG. 2 is a cross-sectional view taken along a line A-A in FIG. 1. A normal direction of a base 10 is defined as a Z direction, an extending direction of a straight line connecting leads 18a and 18b is defined as an X direction, and a direction orthogonal to the X direction and the Y direction is defined as a Y direction.

As illustrated in FIGS. 1 and 2, in a semiconductor device 100 of the first embodiment, a semiconductor chip 20 and passive element chips 25 and 30 are mounted on a package 80. The package 80 includes the base 10, a frame 12, metal layers 14a and 14b, insulating layers 16a and 16b, the leads 18a and 18b, and a bonding layer 36. A mounting region 11 is provided on an upper surface of the base 10. The mounting region 11 is a region where chips such as the semiconductor chip 20 and the passive element chips 25 and 30 are mounted (that is, a region where mounting is possible). A reference potential such as a ground potential is supplied to the base 10. The frame 12 is provided on the base 10 so as to surround the mounting region 11. The metal layers 14a and 14b are provided on an upper surface of the frame 12. The metal layer 14a is provided at the center in the Y direction of a side located in a − direction of the X direction of the frame 12, and the metal layer 14b is provided at the center in the Y direction of a side located in a + direction of the X direction of the frame 12.

The metal layer 14a includes portions 51a to 53a arranged in the X direction, and the metal layer 14b includes portions 51b to 53b arranged in the X direction. Each of the portions 51a and 51b is closer to the mounting region 11, and the portions 52a and 52b are farther from the mounting region 11 than portions 51a and 51b, respectively. The portion 53a is interposed between the portions 51a and 52a in the X direction. The portion 53b is interposed between portions 51b and 52b in the X direction. The insulating layers 16a and 16b extending in the Y direction are provided on the portions 53a and 53b, respectively.

The insulating layer 16a crosses the metal layer 14a in the Y direction and divides the metal layer 14a into the portions 51a and 52a. The insulating layer 16b crosses the metal layer 14b in the Y direction and divides the metal layer 14b into the portions 51b and 52b. The lead 18a is provided on the portion 52a of the metal layer 14a. The lead 18b is provided on the portion 52b of the metal layer 14b. The conductive bonding layer 36 bonds the metal layers 14a and 14b to the leads 18a and 18b, respectively. The metal layer 14a and the lead 18a are electrically connected and short-circuited. The metal layer 14b and the lead 18b are electrically connected and short-circuited. The lead 18a extends from the portion 52a of the metal layer 14a in the − direction of the X direction, and the lead 18b extends from the portion 52b of the metal layer 14b in the + direction of the X direction.

In the mounting region 11, the passive element chip 25, the semiconductor chip 20 and the passive element chip 30 are mounted in this order in the + direction in the X direction. The semiconductor chip 20 includes a substrate 21 and electrodes 22 to 24. The substrate 21 is, for example, a semiconductor substrate. The electrodes 22 and 23 are provided on an upper surface of the substrate 21. The electrode 24 is provided on a lower surface of the substrate 21. The passive element chip 25 includes a substrate 26 and electrodes 27 and 28. The substrate 26 is, for example, a dielectric substrate. The electrode 27 is provided on an upper surface of the substrate 26, and the electrode 28 is provided on a lower surface of the substrate 26. The passive element chip 30 includes a substrate 31 and electrodes 32 and 33. The substrate 31 is, for example, a dielectric substrate. The electrode 32 is provided on an upper surface of the substrate 31, and the electrode 33 is provided on a lower surface of the substrate 31. A conductive bonding layer 34 bonds the base 10 to the electrodes 24, 28 and 33. The electrodes 24, 28 and 33 are electrically connected to and short-circuited to the base 10. Bonding wires 40 electrically connect the portion 51a of the metal layer 14a and the electrode 27. Bonding wires 42 electrically connect the electrode 27 and the electrode 22. Bonding wires 44 electrically connect the electrode 23 and the electrode 32. Bonding wires 46 electrically connect the electrode 32 and the portion 51b of the metal layer 14b.

The base 10 is a plate having conductivity, and is, for example, a copper plate, a metal plate having a laminated structure of a copper layer and a molybdenum layer, or a copper-molybdenum alloy plate. The frame 12 is an insulating layer, for example, a ceramic layer. The ceramic layer is an inorganic insulator layer such as a metal oxide or a metal nitride, and is, for example, a sintered body containing aluminum oxide (for example, Al₂O₃) as a main component. Each of the metal layers 14a and 14b is, for example, a single layer, laminated layers or alloy layers of tungsten, platinum, silver or copper. Each of the insulating layers 16a and 16b is an inorganic insulating layer such as ceramics or an organic insulating layer such as a resin, and is, for example, a sintered body containing aluminum oxide (for example, Al₂O₃) as a main component. Each of the leads 18a and 18b is a metal plate such as a copper plate and has a plating layer such as a gold layer. The bonding layer 36 is a brazing filler metal or a metal paste, and is, for example, a silver-copper alloy. The bonding layer 34 is, for example, a brazing filler metal or a metal paste, and is, for example, a gold-tin or silver paste.

The thickness of the base 10 is, for example, 800 μm to 2000 μm. The thickness of the frame 12 is, for example, 500 μm to 1500 μm. The width of the frame 12 (the width in the X direction in FIG. 2) is, for example, 600 μm to 2000 μm. The thickness of each of the metal layers 14a and 14b is, for example, 10 μm to 100 μm. The thickness of each of the leads 18a and 18b is, for example, 50 μm to 200 μm. The thickness of each of the insulating layers 16a and 16b is, for example, 10 μm to 200 μm. The width of each of the insulating layers 16a and 16b (the width in the X direction in FIG. 2) is, for example, 50 μm to 700 μm. In order to secure the areas of the portions 51a and 51b where the bonding wires 40 and 46 are bonded and the areas of the portions 52a and 52b where the leads 18a and 18b are bonded, the widths of the insulating layers 16a and 16b can be made to be one third or less of the width of the frame 12.

The semiconductor chip 20 includes, for example, a transistor. The transistor is, for example, an FET (Field Effect Transistor), and an example of the FET is a GaN HEMT (Gallium Nitride High Electron Mobility Transistor) or an LDMOS (Laterally Diffused Metal Oxide Semiconductor). The electrodes 22, 23 and 24 are connected to, for example, a gate, a drain and a source. The electrode 22 is an input electrode to which, for example, a high frequency signal is input, and the electrode 23 is an output electrode to which, for example, a high frequency signal is output. When the semiconductor chip 20 has a GaN HEMT, the substrate 21 is, for example, a silicon carbide substrate or a gallium nitride substrate. The electrodes 22 to 24 are metal layers, such as gold layers.

The passive element chips 25 and 30 are, for example, capacitors. Each of the substrates 26 and 31 is a dielectric substrate, for example, and an alumina (aluminum oxide) substrate or a high-dielectric ceramic substrate having a larger relative dielectric constant than that of the alumina substrate. The electrodes 27, 28, 32 and 33 are metal layers, such as gold layers. The substrate 26 and the electrodes 27 and 28 sandwiching the substrate 26 form a capacitor. The substrate 31 and the electrodes 32 and 33 sandwiching the substrate 31 form a capacitor. The bonding wires 40, 42, 44 and 46 form inductors. The bonding wires 40, the passive element chip 25 and the bonding wires 42 form an input matching circuit. The bonding wires 44, the passive element chip 30 and the bonding wires 46 form an output matching circuit.

The high frequency signal input to the lead 18a is input to the electrode 22 through the input matching circuit. The high frequency signal amplified by the semiconductor chip 20 passes through the output matching circuit from the electrode 23 and is output from the lead 18b. When the semiconductor device 100 is used in an amplifier circuit for a base station of mobile communication, the frequency of the high frequency signal is, for example, 0.5 GHz to 10 GHz.

In the first embodiment, an example in which the semiconductor chip 20 and the passive clement chips 25 and 30 are mounted in the mounting region 11 is described as the semiconductor device 100, but the passive element chips 25 and 30 may not be mounted as long as the semiconductor chip 20 is provided.

### Mounting Method of First Embodiment

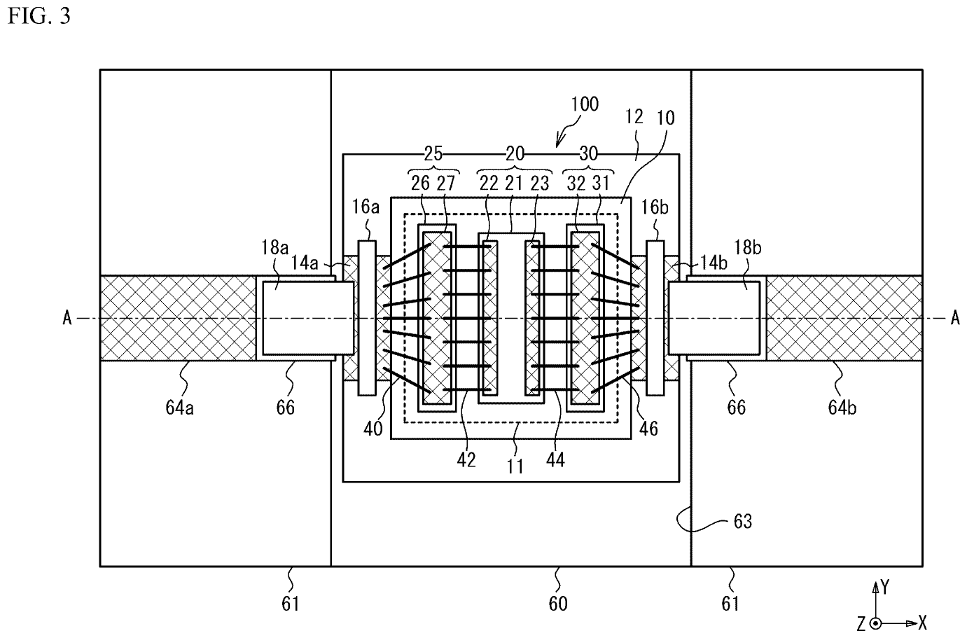

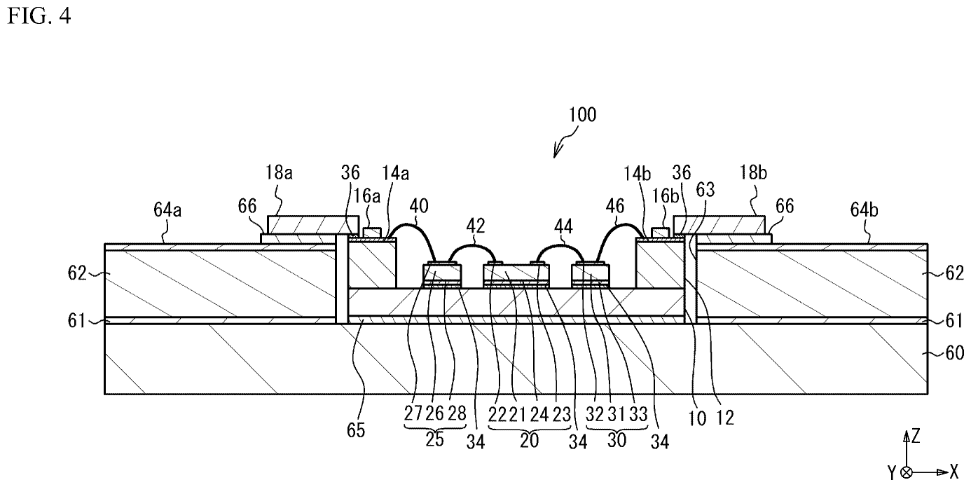

An example in which the semiconductor device 100 is mounted on a housing will be described. FIG. 3 is a plan view of the semiconductor device mounted on the housing according to the first embodiment. FIG. 4 is a cross-sectional view taken along the line A-A in FIG. 3. As illustrated in FIGS. 3 and 4, a substrate 62 is provided on a housing 60. A metal layer 61 is provided on a lower surface of the substrate 62. The metal layer 61 and the housing 60 are bonded by a conductive bonding layer. The substrate 62 is provided with an opening 63. The opening 63 is a groove extending in the Y direction, for example. The housing 60 is exposed from the opening 63. Metal layers 64a and 64b are provided on the substrate 62, and the metal layers 64a and 64b are lines extending in the X direction. The metal layers 61, and 64a and 64b sandwiching the substrate 62 function as transmission lines (for example, microstrip lines) for transmitting high frequency signals. The base 10 of the semiconductor device 100 is bonded to the housing 60 in the opening 63 by using a solder layer 65. The leads 18a and 18b are bonded to the metal layers 64a and 64b, respectively, by a solder 66.

The housing 60 is a metal plate such as a copper plate, an aluminum plate, or a stainless steel plate. The substrate 62 is an insulating substrate, and is a resin substrate such as a glass epoxy resin substrate. The metal layers 61, 64a and 64b are, for example, copper layers or gold layers. The solder layer 65 and the solder 66 are made of, for example, tin-silver-copper.

The high frequency signal is input from the metal layer 64a to the lead 18a, and output from the lead 18b to the metal layer 64b. When the base 10 is bonded to the housing 60, heat generated in the semiconductor chip 20 is released into the housing 60 through the base 10.

### Manufacturing Method of Package of First Embodiment

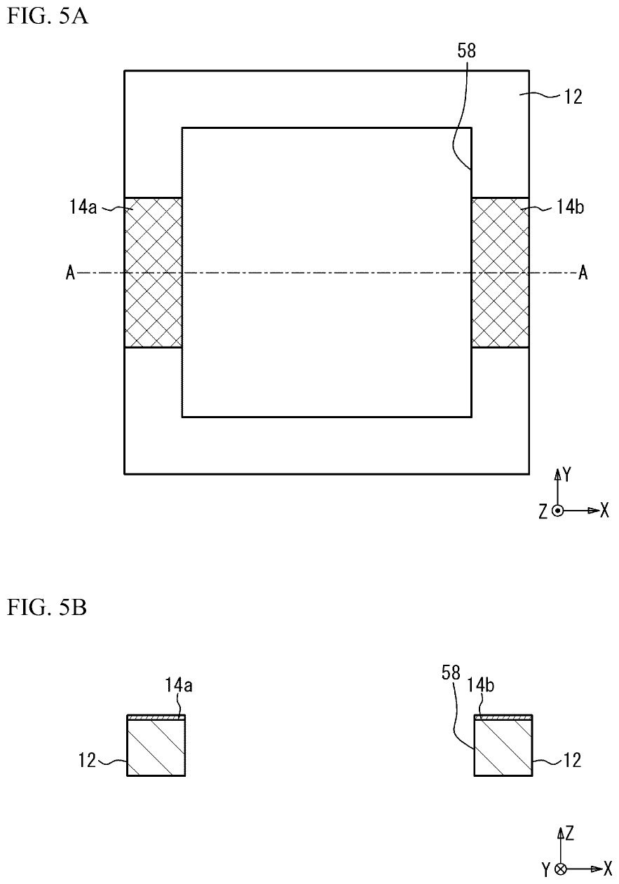

FIGS. 5A to 9 are views illustrating a method of manufacturing the package according to the first embodiment. FIGS. 5A to 9 are views illustrating the manufacturing method of Example 1. FIGS. 5A, 6A, 7A and 8A are plan views, and FIGS. 5B, 6B, 7B, 8B and 9 are views corresponding to the A-A cross section of FIGS. 5A, 6A, 7A and 8A.

As illustrated in FIGS. 5A and 5B, an opening 58 is formed in a green sheet to form the frame 12. The green sheet is a ceramic sheet before firing. The metal layers 14a, and 14b are formed on the frame 12. The metal layers 14a and 14b are formed by pattern printing. A metal layer may be formed on the upper surface of the frame 12 as a circuit pattern other than the metal layers 14a and 14b. The opening 58 may be formed after the metal layers 14a and 14b are formed on the green sheet.

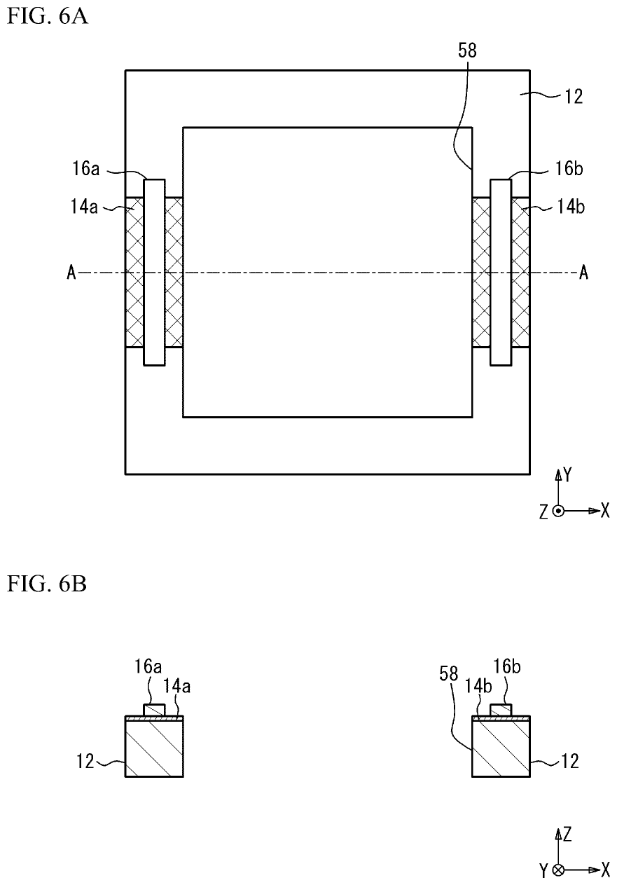

As illustrated in FIGS. 6A and 6B, the insulating layers 16a and 16b are formed on the metal layers 14a and 14b on the frame 12. The insulating layers 16a and 16b are formed by applying a paste material containing particles of an inorganic insulator such as aluminum oxide onto the frame 12. Thereafter, the frame 12 and the insulating layers 16a and 16b are fired.

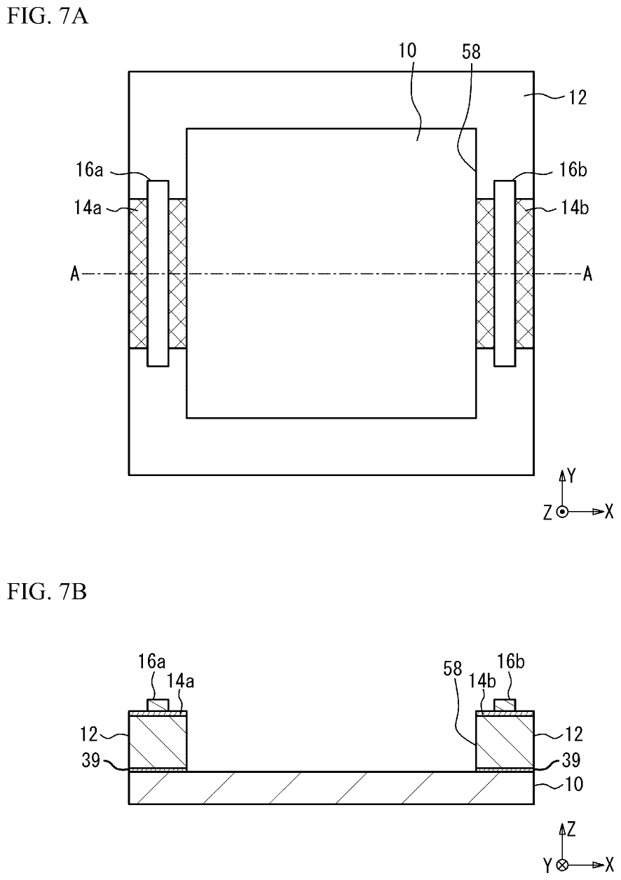

As illustrated in FIGS. 7A and 7B, a bonding layer 39 is applied to a lower surface of the frame 12. The frame 12 is disposed on the base 10 with the bonding layer 39 interposed therebetween.

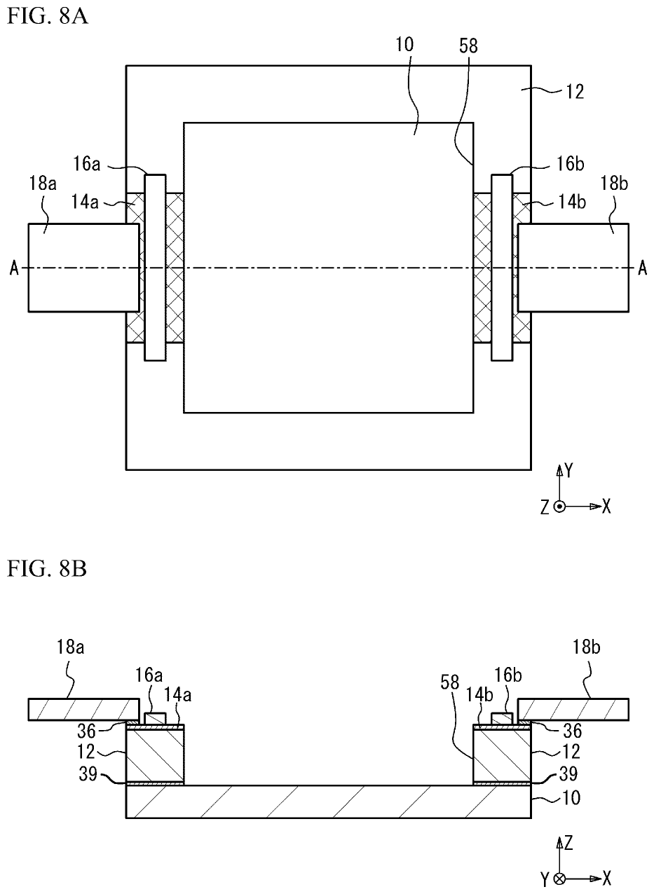

As illustrated in FIGS. 8A and 8B, leads 18a and 18b having the bonding layer 36 applied to the lower surfaces thereof are disposed on the metal layers 14a and 14b. The frame 12 is bonded to the base 10 by heating and curing the bonding layer 39, and the leads 18a and 18b are bonded to the metal layers 14a and 14b by curing the bonding layer 36, respectively. A bonding temperature is lower than a firing temperature of FIGS. 6A and 6B.

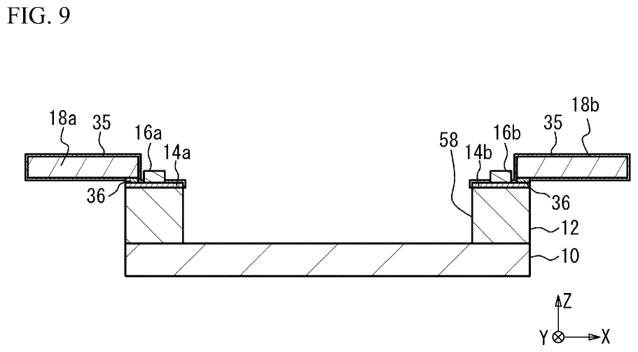

As illustrated in FIG. 9, a metal layer 35 is formed on the exposed surfaces of the metal layers 14a and 14b and the leads 18a and 18b by, for example, plating. The metal layer 35 is a metal having good wettability with solder, and is, for example, a gold plating layer. In FIGS. 1 and 2, the metal layer 35 is not illustrated. In this way, the package of the first embodiment is manufactured.

Thereafter, as illustrated in FIGS. 1 and 2, the semiconductor chip 20 and the passive element chips 25 and 30 are bonded to the mounting region 11 by using the bonding layer 34. A temperature at which the semiconductor chip 20 and the passive element chips 25 and 30 are bonded is lower than the bonding temperature of FIGS. 8A and 8B. Thereafter, the bonding wires 40, 42, 44 and 46 are formed. The semiconductor device 100 of the first embodiment is manufactured as described above.

### First Comparative Example

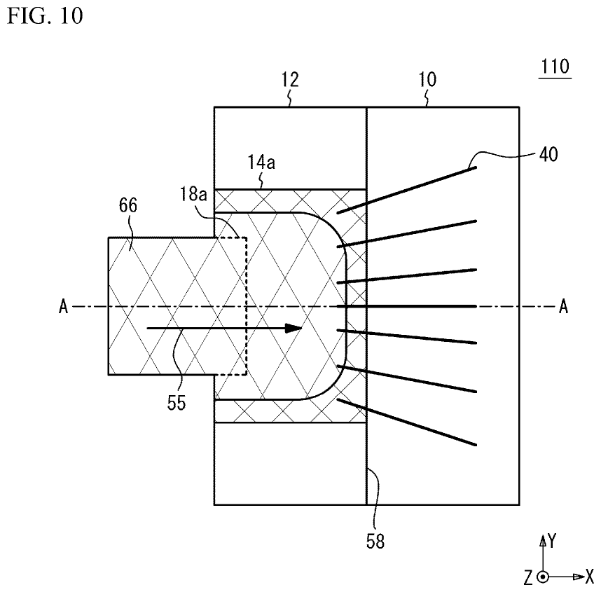

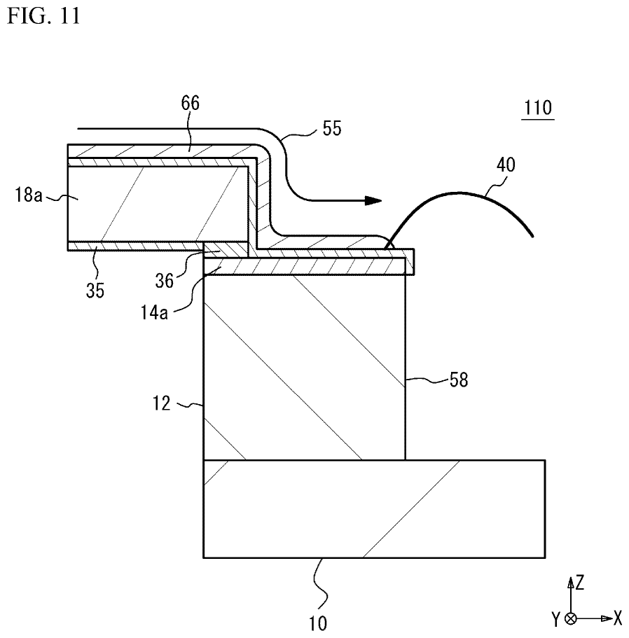

FIG. 10 is an enlarged plan view of a semiconductor device according to a first comparative example, and a plan view in which the vicinity of the metal layer 14a is enlarged. FIG. 11 is a cross-sectional view taken along the line A-A in FIG. 10. As illustrated in FIGS. 10 and 11, when a semiconductor device 110 of the first comparative example is mounted, the lead 18a is soldered to the metal layer 14a of FIGS. 3 and 4, for example. At this time, the metal layer 35 is provided on the surfaces of the leads 18a and the metal layer 14a. The metal layer 35 is, for example, a gold layer, and has good wettability with the solder 66. For this reason, the molten solder 66 may wet and spread through the metal layer 35 on the surface of the lead 18a as indicated by an arrow 55. Further, the solder 66 wets and spreads through the metal layer 35 on the surface of the metal layer 14a to reach portions to which the bonding wires 40 are bonded. This causes defects in the bonding wires 40. For example, when the bonding wires 40 are gold wires, the gold reacts with the solder, and the bonding wires 40 are broken.

### Description of First Embodiment

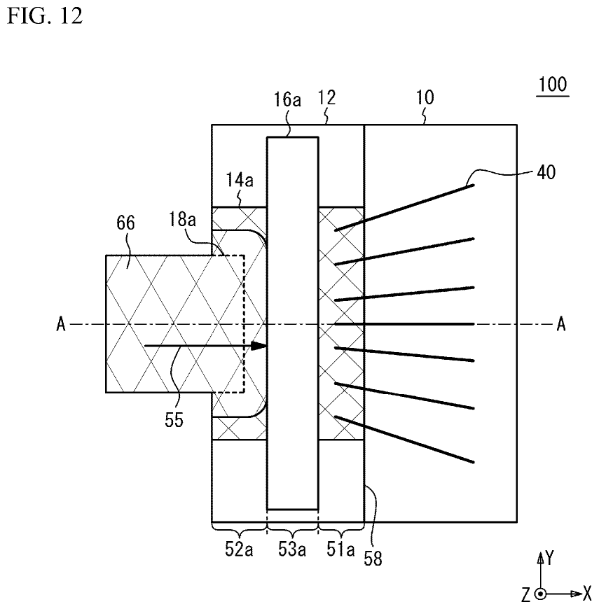

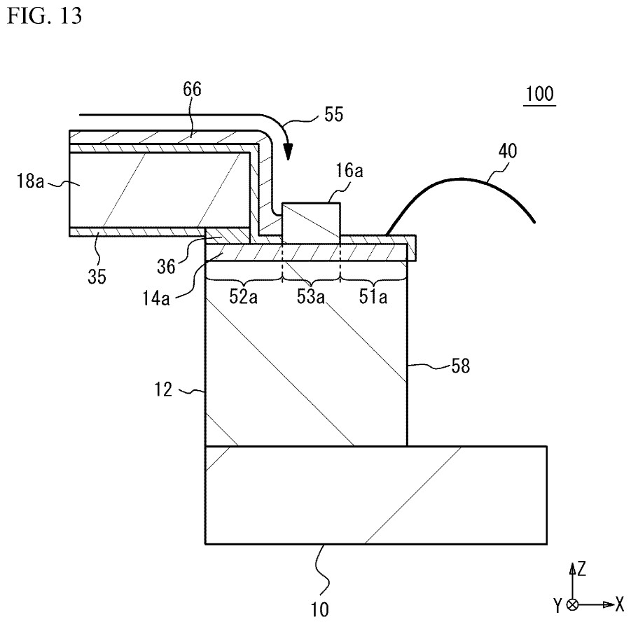

FIG. 12 is an enlarged plan view of the semiconductor device according to the first embodiment, and a plan view in which the vicinity of the metal layer 14a is enlarged. FIG. 13 is a cross-sectional view taken along the line A-A in FIG. 12. As illustrated in FIGS. 12 and 13, in the package 80 according to the first embodiment, the bonding wires 40 (first bonding wire) for electrically connecting the semiconductor chip 20 are bonded to the portion 51a (first portion) of the metal layer 14a (first metal layer). That is, the portion 51a is a portion to which the bonding wires 40 are to be bonded (bondable portion). The lead 18a (first lead) is bonded to the portion 52a (second portion) of the metal layer 14a. The portion 53a (first connecting portion) of the metal layer 14a connects the portion 51a to the portion 52a. The insulating layer 16a (first insulating layer) is provided on the portion 53a in contact with the portion 53a and crosses the metal layer 14a. Thus, since the insulating layer 16a functions as a weir or dam for the solder 66, it is possible to suppress the solder 66 from spreading to the portion 51a and causing defects in the bonding wires 40 as in the first comparative example illustrated in FIGS. 10 and 11. The bonding wires 40 and the lead 18a are electrically connected and short-circuited.

Each of the frame 12 and the insulating layer 16a has ceramics as a main component. This makes it possible to use the frame 12 and the insulating layer 16a having better high frequency characteristics than the high frequency characteristics of a resin. Since ceramics has a smaller linear expansion coefficient than resin, a thermal stress between the metal layer 14a and the insulating layer 16a can be reduced. Further, since the linear expansion coefficients of the frame 12 and the insulating layer 16a are close to each other, the thermal stress can be reduced. The frame 12 and the insulating layer 16a have the same material as a main component. This makes it possible to make the linear expansion coefficients of the frame 12 and the insulating layer 16a substantially the same and to reduce the thermal stress. The frame 12 and the insulating layer 16a may have aluminum oxide (alumina) as a main component. This makes it possible to use the frame 12 and the insulating layer 16a having good high frequency characteristics. The frame 12 and the insulating layer 16a may contain an organic insulator or an inorganic insulator other than the main component, such as a binder. The content of the main component in the frame 12 and the insulating layer 16a is, for example, 50 mol % or more, and preferably 80 mol % or more.

The wettability of the surface of the insulating layer 16a with the solder 66 is worse than the wettability of the surface of the metal layer 14a with the solder 66. This can suppress the solder 66 from spreading on the surface of the insulating layer 16a. Therefore, the insulating layer 16a can function as the weir or dam for the solder 66.

As illustrated in FIGS. 1 and 2, also in the metal layer 14b, the bonding wires 46 (second bonding wire) for electrically connecting the semiconductor chip 20 are bonded to the portion 51b (third portion) of the metal layer 14b (second metal layer). The lead 18b (second lead) is bonded on the portion 52b (fourth portion) of the metal layer 14b. The portion 53b (second connecting portion) of the metal layer 14b connects the portion 51b to the portion 52b. The insulating layer 16b (second insulating layer) is provided on the portion 53b in contact with the portion 53b and crosses the metal layer 14b. This can prevent the solder 66 from spreading to the portion 51b and causing defects in the bonding wires 46, as in the case of the metal layer 14a. In this way, when the plurality of metal layers 14a and 14b are provided, the insulating layers 16a and 16b can be provided on the plurality of metal layers 14a and 14b, respectively.

### Second Embodiment

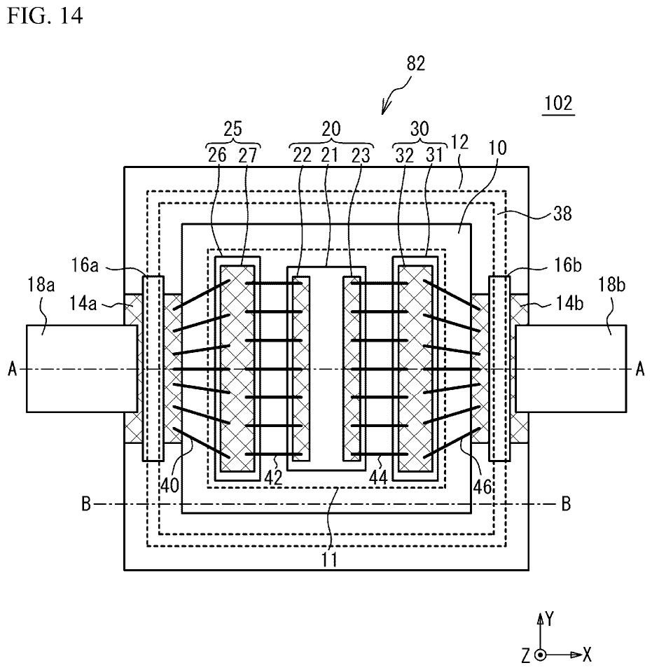

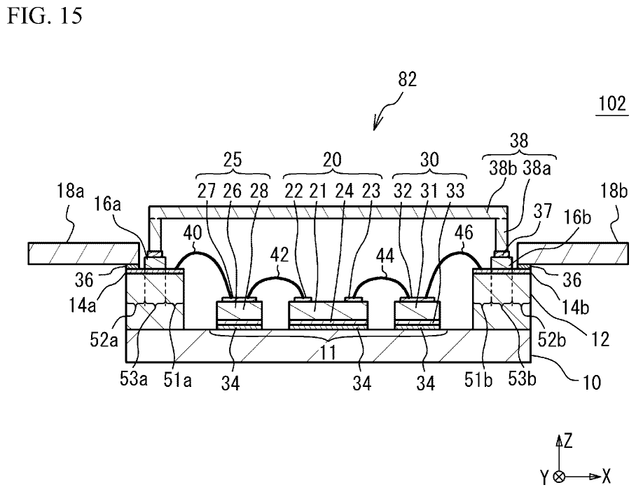

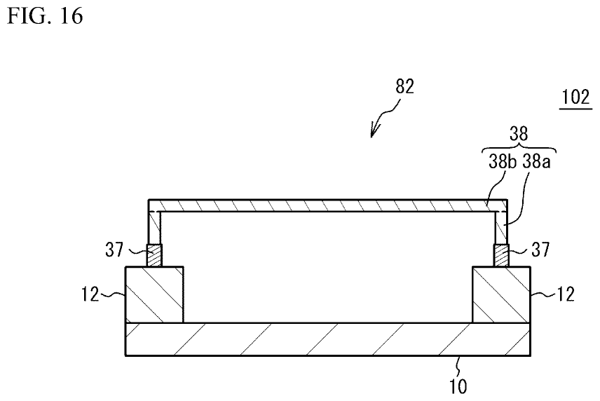

FIG. 14 is a plan view of a semiconductor device according to a second embodiment. FIGS. 15 and 16 are cross-sectional views taken along the line A-A and the line B-B of FIG. 14, respectively. As illustrated in FIGS. 14 to 16, a semiconductor device 102 of the second embodiment includes a package 82. The package 82 includes a lid 38. The lid 38 includes a frame portion 38a and a ceiling portion 38b. The frame portion 38a surrounds the mounting region 11 in planar view. A bonding layer 37 bonds the lower surface of the frame portion 38a to the upper surface of the frame 12 and the upper surfaces of the insulating layers 16a and 16b. The ceiling portion 38b is provided so as to cover the mounting region 11. The base 10, the frame 12 and the lid 38 hermetically seal the semiconductor chip 20 and the passive element chips 25 and 30 in an air gap.

The lid 38 is an insulating plate made of, for example, ceramics. The lid 38 may be a metal plate. The bonding layer 37 is a resin adhesive such as an epoxy resin. As illustrated in FIGS. 15 and 16, the upper surface of the frame 12 and the upper surfaces of the insulating layers 16a and 16b are different in height from each other. The bonding layer 37 can absorb the difference in height between the upper surface of the frame 12 and the upper surfaces of the insulating layers 16a and 16b.

### Second Comparative Example

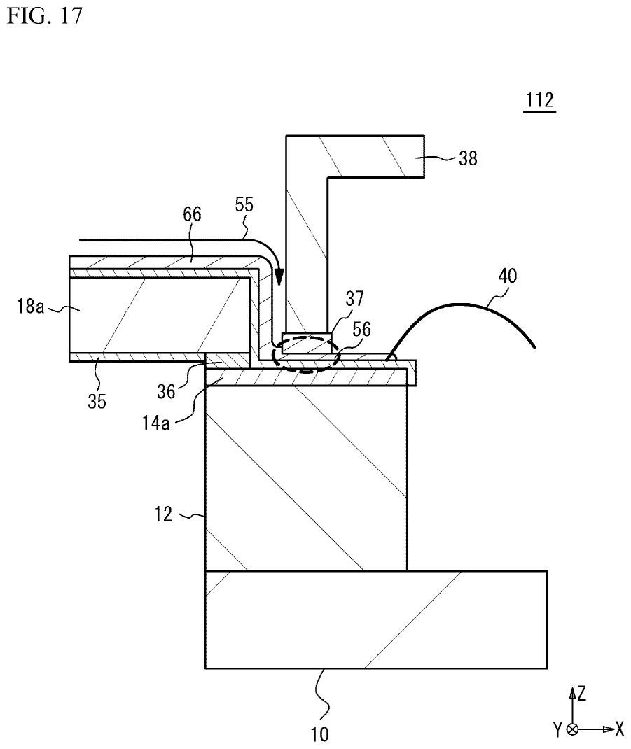

FIG. 17 is an enlarged cross-sectional view of a semiconductor device according to a second comparative example. As illustrated in FIG. 17, in a semiconductor device 112 of the second comparative example, the insulating layer 16a is not provided, and the lid 38 is bonded on the metal layer 14a by using the bonding layer 37. The other configurations of the second comparative example are the same as those of the second embodiment. The solder 66 moves over the surfaces of the leads 18a and the metal layer 14a as indicated by the arrow 55. When there is high adhesion between the metal layer 14a and the bonding layer 37, the bonding layer 37 serves as a weir or dam for the solder 66.

However, the adhesion between the metal layer 14a such as a gold layer and the bonding layer 37 such as the resin adhesive is low. In particular, the bonding wires 40 are bonded to the upper surface of the metal layer 14a. For this reason, the flatness of the upper surface of the metal layer 14a is high so as to improve the bonding property between the bonding wires 40 and the metal layer 14a. Therefore, the adhesion between the metal layer 14a and the bonding layer 37 is further reduced. For this reason, when the temperature is repeatedly increased and decreased, the metal layer 14a and the bonding layer 37 may be peeled off from each other. In particular, the linear expansion coefficient of gold is 14×10⁻⁶ K⁻¹, the linear expansion coefficient of alumina is 7×10⁻⁶ K⁻¹, and the linear expansion coefficient of epoxy resin adhesive is 30×10⁻⁶K⁻¹ to 80×10⁻⁶K⁻¹. Thus, a resin-based adhesive has a linear expansion coefficient larger than the linear expansion coefficient of the metal. Accordingly, when the temperature is repeatedly increased and decreased, the large thermal stress is applied between the metal layer 14a and the bonding layer 37, and the bonding layer 37 is easily peeled from the metal layer 14a. When the bonding layer 37 is peeled off, the solder 66 spreads between the metal layer 14a and the bonding layer 37 as illustrated by a broken line ellipse 56, and the solder 66 may reach the bonding portion of the bonding wires 40. This causes the bonding wires 40 to be broken.

### Description of Second Embodiment

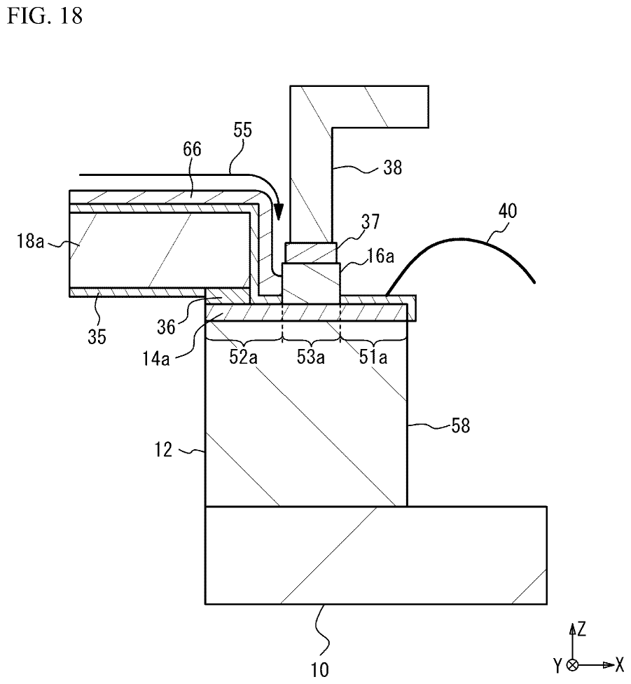

FIG. 18 is an enlarged cross-sectional view of a semiconductor device according to a second embodiment. As illustrated in FIG. 18, in the semiconductor device 102 of the second embodiment, the insulating layer 16a is provided on the metal layer 14a, and the bonding layer 37 is provided on the insulating layer 16a. The lid 38 is bonded to the upper surface of the frame 12 and the upper surface of the insulating layer 16a by using the resin adhesive as the bonding layer 37. When the insulating layer 16a is made of ceramics and the metal layer 14a is interposed between the frame 12 and the insulating layer 16a and fired as illustrated in FIGS. 6A and 6B, the adhesion between the metal layer 14a and the insulating layer 16a is high. The insulating layer 16a has a large roughness on the upper surface thereof, and the adhesion between the insulating layer 16a and the bonding layer 37 is enhanced by an anchor effect. Furthermore, when the main components of the frame 12 and the insulating layer 16a are the same, the linear expansion coefficients of the frame 12 and the insulating layer 16a are substantially the same, and the difference in linear expansion coefficient between the metal layer 14a and the insulating layer 16a is smaller than the difference in linear expansion coefficient between the metal layer 14a and the bonding layer 37. As a result, the thermal stress between the metal layer 14a and the insulating layer 16a is smaller than the thermal stress between the metal layer 14a and the bonding layer 37 of the second comparative example. Therefore, the insulating layer 16a is less likely to be peeled off from the metal layer 14a. As a result, the insulating layer 16a becomes a weir or dam for the solder 66. Therefore, it is possible to suppress the solder 66 from reaching the bonding wires 40 and breaking the bonding wires 40. In the second embodiment, an example in which the frame portion 38a and the insulating layers 16a and 16b overlap each other in planar view as illustrated in FIG. 14 is described, but the frame portion 38a and the insulating layers 16a and 16b may not overlap each other.

In order to reduce the thermal stress of the frame 12, the insulating layer 16a and the lid 38, the lid 38 may be made of ceramics. The main component of the lid 38 may be the same as the main components of the frame 12 and the insulating layer 16a. The main component of the lid 38 is, for example, aluminum oxide.

### Third Embodiment

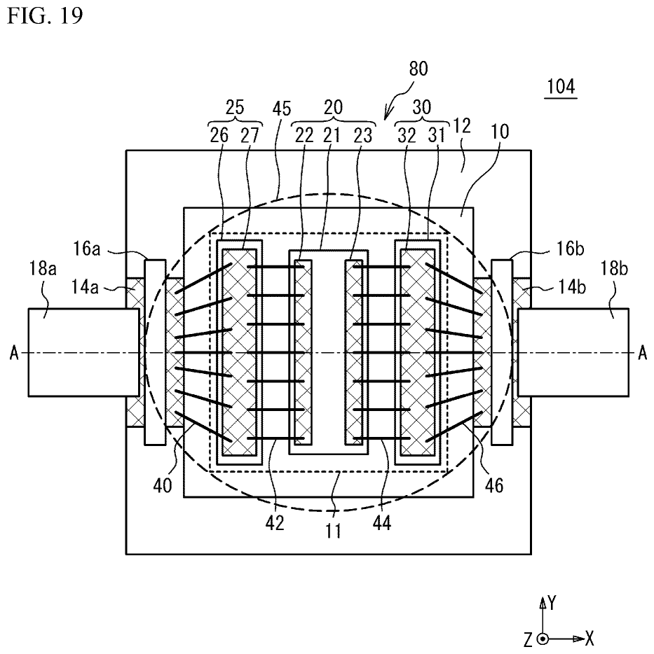

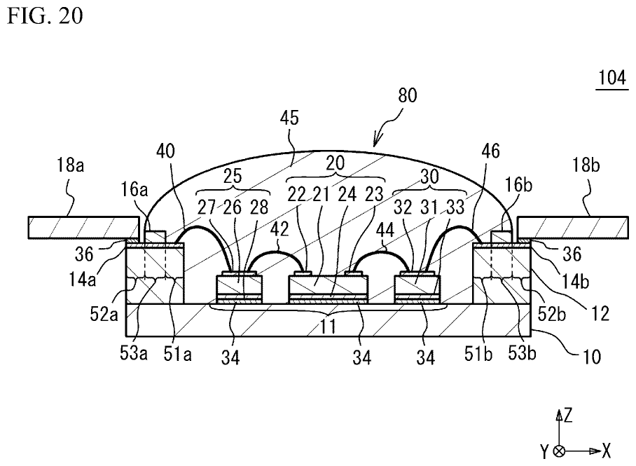

A third embodiment is an example using a potting resin. FIG. 19 is a plan view of a semiconductor device according to the third embodiment. FIG. 20 is a cross-sectional view taken along the line A-A in FIG. 19. In FIG. 19, a resin sealing material 45 is illustrated by a broken line. As illustrated in FIGS. 19 and 20, in a semiconductor device 104 of the third embodiment, the resin sealing material 45 is potted on the package 80. The resin sealing material 45 is bonded to the upper surface of the frame 12 and the upper surfaces of the metal layers 14a and 14b, and seals the semiconductor chip 20. The resin sealing material 45 is, for example, an epoxy resin, a urethane resin, or a silicon resin. The resin sealing material 45 is softer than the lid 38 in the second embodiment. Therefore, the stress between the resin scaling material 45 and the frame 12 is relieved. However, the adhesion between the resin sealing material 45 and the metal layer 14a is low. For this reason, if the insulating layers 16a and 16b are not provided, the solder 66 enters between the metal layers 14a and 14b and the resin sealing material 45, and the bonding wire 40 is easily broken. Therefore, by providing the insulating layers 16a and 16b, it is possible to suppress the solder 66 from being transmitted between the metal layers 14a and 14b and the resin scaling material 45.

### Fourth Embodiment

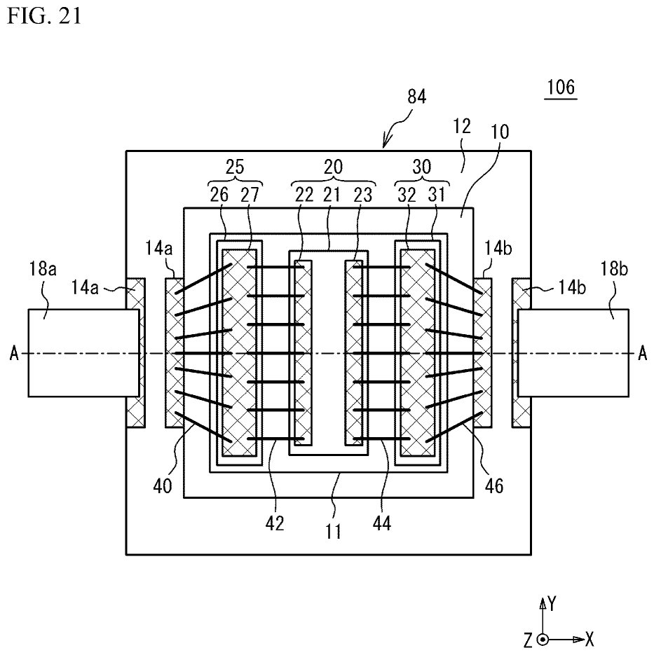

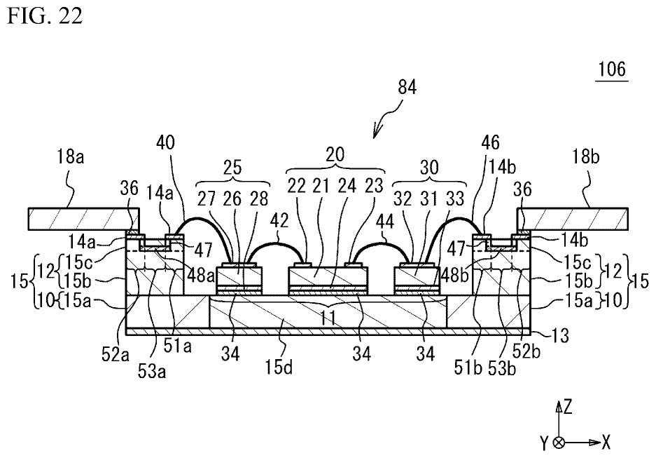

A fourth embodiment is an example in which a multilayer printed circuit board is used as the frame. FIG. 21 is a plan view of a semiconductor device according to a fourth embodiment. FIG. 22 is a cross-sectional view taken along the line A-A in FIG. 21. As illustrated in FIGS. 21 and 22, a semiconductor device 106 of the fourth embodiment includes a package 84. The package 84 includes a multilayer substrate 15. The multilayer substrate 15 includes laminated insulating layers 15a to 15c. The insulating layer 15a is a lowermost insulating layer and corresponds to the base 10. A metal plate 15d (copper coin) is embedded in the insulating layer 15a. The metal plate 15d corresponds to the mounting region 11. The semiconductor chip 20 and the passive element chips 25 and 30 are mounted on the metal plate 15d. A metal layer 13 is provided on the lower surfaces of the insulating layer 15a and the metal plate 15d. The insulating layers 15b and 15c correspond to the frame 12. Metal layers 48a and 48b are provided between the insulating layers 15b and 15c. The metal layers 14a and 14b are provided on the upper surface of the insulating layer 15c.

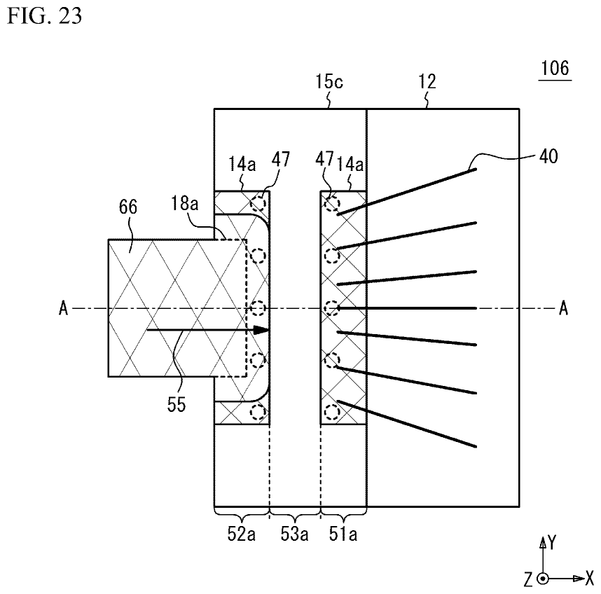

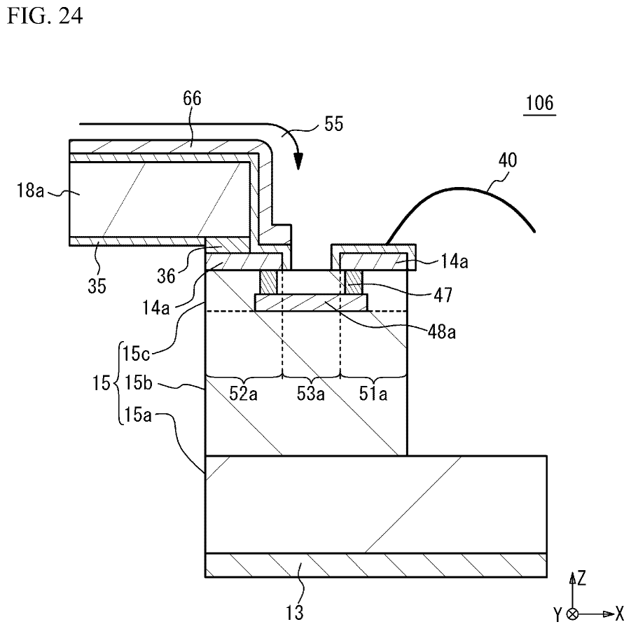

FIG. 23 is an enlarged plan view of the semiconductor device according to the fourth embodiment. FIG. 24 is a cross-sectional view taken along the line A-A in FIG. 23. In FIG. 23, through holes 47 are illustrated by broken lines. As illustrated in FIGS. 23 and 24, the metal layer 14a is provided on the portions 51a and 52a, but not on the portion 53a. In the portion 53a, the insulating layer 15c is exposed from the metal layer 14a. In the portion 53a, the metal layer 48a is provided under the insulating layer 15c. Both ends of the metal layer 48a in the X direction are electrically connected and short-circuited to the metal layers 14a of the portions 51a and 52a, respectively, via metal layers in the through holes 47 penetrating the insulating layer 15c. As a result, the portions 51a and 52a are electrically connected to each other through the metal layer 48a.

The wettability of the surface of the insulating layer 15c of the portion 53a with the solder is worse than the wettability of the surface of the metal layer 35 with the solder. As indicated by the arrow 55, even if the solder 66 wets and spreads on the metal layer 35 on the surface of the lead 18a and the metal layer 14a, the solder 66 does not wets and spreads on the upper surface of the insulating layer 15c. This can suppress the solder 66 from spreading to the portion 51a, and suppress the bonding wires 40 from breaking.

The insulating layers 15a to 15c are resin layers such as glass epoxy resin. The metal plate 15d is, for example, a copper plate. The metal layer 48a is, for example, a single layer, a laminate or an alloy layer of silver, gold or copper. The other configurations of the fourth embodiment are the same as those of the first embodiment, and the description thereof is omitted.

According to the fourth embodiment, the portions 51a and 52a of the metal layer 14a are separated from each other on the upper surface of the frame 12, and the upper surface of the frame 12 is exposed from the metal layer 14a so as to cross the metal layer 14a in a region separating the portions 51a and 52a. The metal layer 48a (first wiring) electrically connects the portion 51a to the portion 52a. By using the upper surface of the frame 12 as the weir or dam for the solder 66, it is possible to suppress the solder 66 from spreading to the bonding wires 40 and causing the defects in the bonding wires 40. The bonding wires 40 and the lead 18a are electrically connected and short-circuited by the metal layer 48a.

The wettability of the surface of the frame 12 with the solder 66 is worse than the wettability of the surface of the metal layer 14a with the solder 66. This can suppress the solder 66 from spreading on the surface of the frame 12. Therefore, the frame 12 can function as the weir or dam for the solder 66.

As illustrated in FIGS. 21 and 22, also in the metal layer 14b, the portions 51b and 52b of the metal layer 14b are separated from each other on the upper surface of the frame 12, and the upper surface of the frame 12 is exposed from the metal layer 14b so as to cross the metal layer 14b in a region separating the portions 51b and 52b. The metal layer 48b (second wiring) electrically connects the portion 51b to the portion 52b. This can suppress the solder 66 from spreading to the portion 51b and causing the defects in the bonding wires 46, as in the case of the metal layer 14a.

In the case where the multilayer printed circuit board is used for the frame as in the fourth embodiment, the lid 38 may be bonded to the upper surface of the frame 12 and the upper surface of the insulating layer 15c to seal the semiconductor chip 20 as in the second embodiment. This can suppress the solder 66 from passing between the metal layers 14a and 14b and the lid 38 and reaching the bonding wires 40 and 46.

Also, when the multilayer printed circuit board is used for the frame 12, the resin sealing material 45 may be bonded to the upper surface of the frame 12 and the upper surfaces of the metal layers 14a and 14b to seal the semiconductor chip 20 as in the third embodiment. This can suppress the solder 66 from passing between the metal layers 14a and 14b and the resin sealing material 45 and reaching the bonding wires 40 and 46.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A package comprising:
a base having a mounting region on which a semiconductor chip is to be mounted;
a frame provided on the base so as to surround the mounting region;
a first metal layer provided on an upper surface of the frame, the first metal layer including a first portion to which a first bonding wire electrically connecting the semiconductor chip is to be bonded, a second portion farther from the mounting region than the first portion, and a first connecting portion connecting the first portion to the second portion;
a first insulating layer provided on the first connecting portion in contact with the first connecting portion, the first insulating layer crossing the first metal layer; and
a first lead bonded on the second portion.

2. The package according to claim 1, wherein each of the frame and the first insulating layer has ceramics as a main component.

3. The package according to claim 1, wherein
a wettability of a surface of the first insulating layer with a solder is worse than a wettability of a surface of the first metal layer with the solder.

4. The package according to claim 1, further comprising:
a second metal layer provided on an upper surface of the frame, the second metal layer including a third portion to which a second bonding wire electrically connecting the semiconductor chip is to be bonded, a fourth portion farther from the mounting region than the third portion, and a second connecting portion connecting the third portion to the fourth portion;
a second insulating layer provided on the second connecting portion in contact with the second connecting portion, the second insulating layer crossing the second metal layer; and
a second lead bonded on the fourth portion.

5. A package comprising:
a base having a mounting region on which a semiconductor chip is to be mounted;
a frame provided on the base so as to surround the mounting region;
a first metal layer provided on an upper surface of the frame, the first metal layer including a first portion to which a first bonding wire electrically connecting the semiconductor chip is to be bonded, and a second portion farther from the mounting region than the first portion and separated from the first portion on an upper surface of the frame;
a first wiring provided in the frame and electrically connecting the first portion to the second portion; and
a first lead bonded on the second portion;
wherein the upper surface of the frame is exposed from the first metal layer so as to cross the first metal layer in a region separating the first portion and the second portion.

6. The package according to claim 5, wherein
a wettability of a surface of the frame with a solder is worse than a wettability of a surface of the first metal layer with the solder.

7. The package according to claim 5, further comprising:
a second metal layer provided on the upper surface of the frame, the second metal layer including a third portion to which a second bonding wire electrically connecting the semiconductor chip is to be bonded, and a fourth portion farther from the mounting region than the third portion;
a second wiring provided in the frame and electrically connecting the third portion to the fourth portion; and
a second lead bonded on the fourth portion;
wherein the upper surface of the frame is exposed from the second metal layer so as to cross the second metal layer in a region separating the third portion and the fourth portion.

8. A semiconductor device comprising:
the package according to claim 1; and
the semiconductor chip mounted on the base.

9. The semiconductor device according to claim 8, comprising
a resin sealing material bonded to the upper surface of the frame and an upper surface of the first metal layer to seal the semiconductor chip.

10. A semiconductor device comprising:
the package according to claim 2;
the semiconductor chip mounted on the base; and
a lid bonded to the upper surface of the frame and an upper surface of the first insulating layer by using a resin adhesive to seal the semiconductor chip.

11. A semiconductor device comprising:
the package according to claim 5; and
the semiconductor chip mounted on the base.

12. The semiconductor device according to claim 11, comprising
a resin sealing material bonded to the upper surface of the frame and an upper surface of the first metal layer to seal the semiconductor chip.
